(19) United States
(12) Patent Application Publication
(10) Pub. No.: US 2025/0314693 A1
(43) Pub. Date: Oct. 9, 2025

(54) SEMICONDUCTOR INTEGRATED CIRCUIT

(71) Applicants: Kabushiki Kaisha Toshiba, Tokyo (JP); Toshiba Electronic Devices & Storage Corporation, Tokyo (JP)

(72) Inventor: Tsuneyuki HAYASHI, Kodaira Tokyo (JP)

(21) Appl. No.: 18/824,698

(22) Filed: Sep. 4, 2024

(30) Foreign Application Priority Data
Apr. 9, 2024 (JP) 2024-062927

(51) Int. Cl. G01R 31/28

(52) U.S. Cl. CPC G01R 31/2863

(57) ABSTRACT

A semiconductor integrated circuit includes a first terminal and a second terminal. A resistance value between the first terminal and the second terminal changes with a change of an input voltage which is externally input.

### CROSS-REFERENCE TO RELATED APPLICATION

Priority is claimed on Japanese Patent Application No. 2024-062927, filed Apr. 9, 2024, the content of which is incorporated herein by reference.

### BACKGROUND OF THE INVENTION

### Field of the Invention

An embodiment of the present invention relates to a semiconductor integrated circuit.

### Description of Related Art

For example, a plurality of types of semiconductor integrated circuits may be discriminated between through a test which is externally performed. In this case, when characteristics which are ascertained by externally testing a semiconductor integrated circuit are close between a plurality of types of semiconductor integrated circuits, it may be difficult to discriminate between the semiconductor integrated circuits.

### BRIEF DESCRIPTION OF THE DRAWINGS

FIG. 1 is a diagram illustrating a semiconductor integrated circuit according to a first embodiment.

FIG. 2 is a circuit diagram illustrating a part of the semiconductor integrated circuit according to the first embodiment.

FIG. 3 is a graph illustrating an example of a change of a resistance value between a control terminal and a ground terminal according to the first embodiment.

FIG. 4 is a circuit diagram illustrating a semiconductor integrated circuit according to a second embodiment.

FIG. 5 is a graph illustrating an example of a change of a resistance value between a power supply terminal and a control terminal according to the second embodiment.

FIG. 6 is a circuit diagram illustrating a semiconductor integrated circuit according to a third embodiment.

FIG. 7 is a circuit diagram illustrating a semiconductor integrated circuit according to a fourth embodiment.

FIG. 8 is a graph illustrating an example of a change of a resistance value between a control terminal and a ground terminal according to the fourth embodiment.

FIG. 9 is a graph illustrating an example in which a resistance value between a first terminal and a second terminal according to a modified example changes in two steps.

### DETAILED DESCRIPTION OF THE INVENTION

A semiconductor integrated circuit according to an embodiment includes a first terminal and a second terminal. A resistance value between the first terminal and the second terminal changes with a change of an input voltage which is externally input.

Hereinafter, a semiconductor integrated circuit according to an embodiment will be described with reference to the accompanying drawings.

### First Embodiment

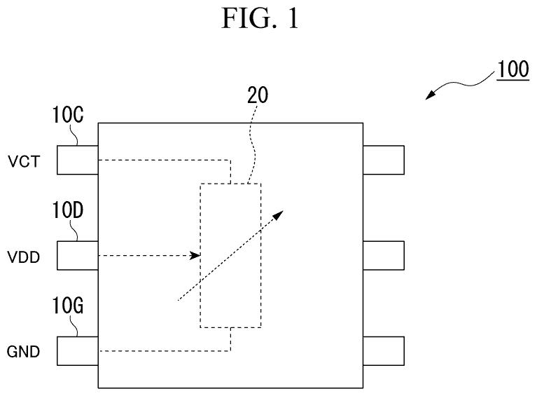

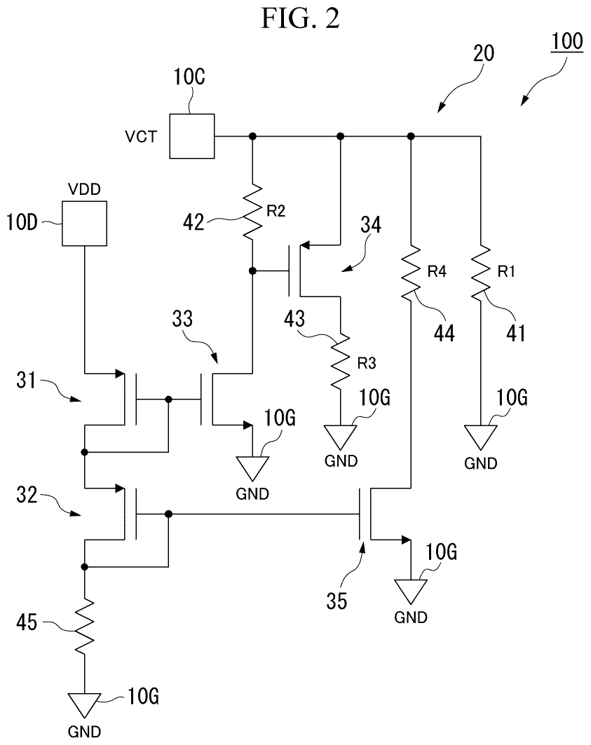

FIG. 1 is a diagram illustrating a semiconductor integrated circuit 100 according to a first embodiment. FIG. 2 is a circuit diagram illustrating a part of the semiconductor integrated circuit 100 according to the first embodiment. The semiconductor integrated circuit 100 illustrated in FIG. 1 is a packaged semiconductor chip. As illustrated in FIG. 1, the semiconductor integrated circuit 100 includes a power supply terminal 10D, a ground terminal 10G, a control terminal 10C, and a switching circuit 20. The power supply terminal 10D, the ground terminal 10G, and the control terminal 10C are exposed to the outside. A power supply voltage VDD is applied to the power supply terminal 10D. A ground GND is connected to the ground terminal 10G. A control voltage VCT is applied to the control terminal 10C. In the first embodiment, the control terminal 10C corresponds to a “first terminal,” the ground terminal 10G corresponds to a “second terminal,” the power supply terminal 10D corresponds to a “third terminal,” and the power supply voltage VDD corresponds to an “input voltage.”

The switching circuit 20 is provided between the control terminal 10C which is a first terminal and the ground terminal 10G which is a second terminal. As illustrated in FIG. 2, the switching circuit 20 includes a plurality of transistors 31 to 35 and a plurality of resistive elements 41 to 45. In the first embodiment, the plurality of transistors 31 to 35 are field effect transistors (FETs). The transistor 31, the transistor 32, and the transistor 34 are P-channel metal-oxide semiconductor field effect transistors (MOSFETs). The transistor 33 and the transistor 35 are N-channel MOSFETs.

The transistor 31 and the transistor 32 are provided between the power supply terminal 10D to which a power supply voltage VDD is applied and the ground terminal 10G. The transistor 31 and the transistor 32 are connected in series. The source terminal of the transistor 31 is connected to the power supply terminal 10D. The drain terminal of the transistor 31 is connected to the source terminal of the transistor 32. The drain terminal of the transistor 32 is connected to the ground GND via the resistive element 45. The gate terminal of the transistor 31 is connected to the drain terminal of the transistor 31. The gate terminal of the transistor 32 is connected to the drain terminal of the transistor 32. Accordingly, the transistor 31 and the transistor 32 are diode-connected. The transistor 31 and the transistor 32 in the first embodiment correspond to a “first transistor.”

In the circuit according to the present disclosure, “a certain element is provided between second element and third element” means that the certain element is provided in a circuit extending from one of the other elements to another of the other elements.

The transistors 33, 34, and 35 are provided between the control terminal 10C and the ground terminal 10G. The drain terminal of the transistor 33 is connected to the control terminal 10C via the resistive element 42. The source terminal of the transistor 33 is connected to the ground GND. The gate terminal of the transistor 33 is connected to the gate terminal of the transistor 31. The source terminal of the transistor 34 is connected to the control terminal 10C. The drain terminal of the transistor 34 is connected to the ground GND via the resistive element 43. The gate terminal of the transistor 34 is connected to the drain terminal of the transistor 33. The drain terminal of the transistor 35 is connected to the control terminal 10C via the resistive element 44. The source terminal of the transistor 35 is connected to the ground GND. The gate terminal of the transistor 35 is connected to the gate terminal of the transistor 32. The transistor 33, the transistor 34, and the transistor 35 in the first embodiment correspond to a “second transistor.”

It is assumed that the absolute values of threshold voltages of the transistors 31 to 35 are the same. The absolute values of the threshold voltages of the transistors 31 to 35 may be different from each other. The on-resistance values of the transistors 33, 34, and 35 are much smaller than the resistance values of the resistive elements 42, 43, and 44. The on-resistance values of the transistors 33, 34, and 35 are equal to or less than, for example, 1/several hundreds of the resistance values of the resistive elements 42, 43, and 44. The on-resistance values of the transistors 33, 34, and 35 are not particularly limited.

One end of the resistive element 41 is connected to the control terminal 10C. The other end of the resistive element 41 is connected to the ground GND. The resistive element 41 in the first embodiment is a resistive element that is connected between the control terminal 10C which is a first terminal and the ground terminal 10G which is a second terminal without using a transistor.

The resistive elements 42, 43, and 44 are resistive elements that are connected in series to the transistors 33, 34, and 35, respectively, between the control terminal 10C and the ground terminal 10G. The resistive element 42 is connected in series to the transistor 33. The resistive element 43 is connected in series to the transistor 34. The resistive element 44 is connected in series to the transistor 35. One end of the resistive element 42 is connected to the control terminal 10C. The other end of the resistive element 42 is connected to the drain terminal of the transistor 33 and the gate terminal of the transistor 34. One end of the resistive element 43 is connected to the drain terminal of the transistor 34. The other end of the resistive element 43 is connected to the ground GND. One end of the resistive element 44 is connected to the control terminal 10C. The other end of the resistive element 44 is connected to the drain terminal of the transistor 35. One end of the resistive element 45 is connected to the drain terminal of the transistor 32. The other end of the resistive element 45 is connected to the ground GND.

The resistive elements 41, 42, 43, and 44 are resistive elements that can serve as a resistor between the control terminal 10C which is a first terminal and the ground terminal 10G which is a second terminal. In the first embodiment, when the power supply voltage VDD which is an input voltage changes, the state of the switching circuit 20 switches, and a combination of the resistive elements 41 to 44 serving as a resistor between the control terminal 10C and the ground terminal 10G changes. Accordingly, when the power supply voltage VDD which is externally input changes, a resistance value CR1 between the control terminal 10C and the ground terminal 10G changes.

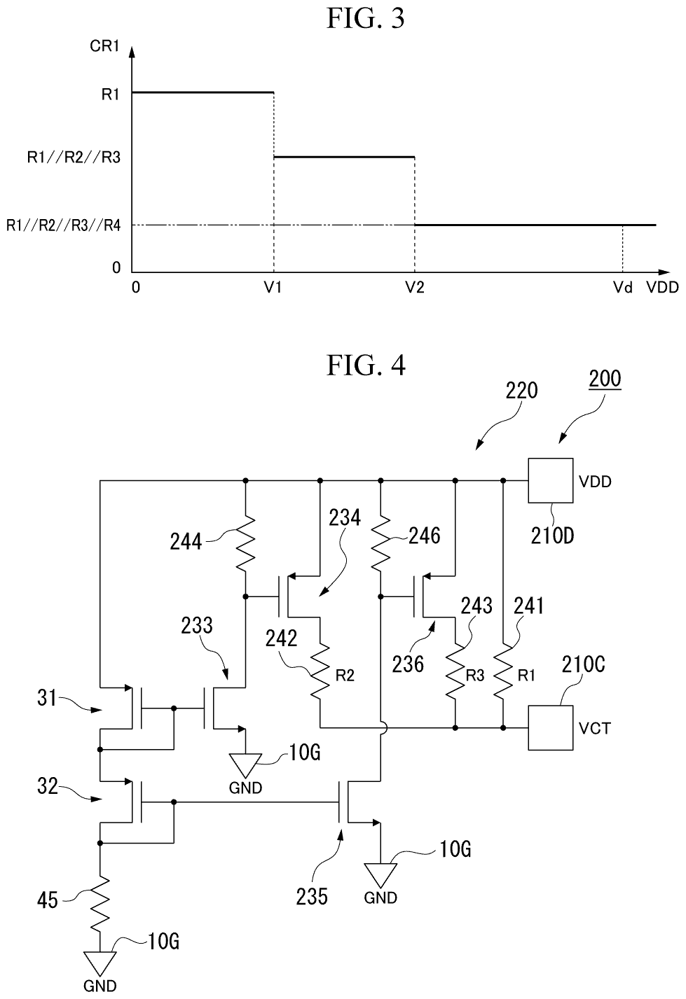

FIG. 3 is a graph illustrating an example of a change of the resistance value CR1 between the control terminal 10C and the ground terminal 10G. In FIG. 3, the horizontal axis represents the power supply voltage VDD, and the vertical axis represents the resistance value CR1 between the control terminal 10C and the ground terminal 10G. In FIGS. 2 and 3, R1 denotes a resistance value of the resistive element 41, R2 denotes a resistance value of the resistive element 42, R3 denotes a resistance value of the resistive element 43, and R4 denotes a resistance value of the resistive element 44. The resistance values R1 to R4 of the resistive elements 41 to 44 may be the same or different from each other. In the example illustrated in FIG. 3, a control voltage VCT that is applied to the control terminal 10C is a constant voltage which is equal to or greater than the absolute value of the threshold voltage of the transistor 34.

As illustrated in FIG. 3, when the power supply voltage VDD is equal to or higher than 0 V and is lower than a voltage value V1, the resistance value CR1 is the resistance value of the resistive element 41. The voltage value V1 is a voltage value when the transistor 31 is turned on. The voltage value V1 is, for example, the same as the threshold voltage of the transistor 31.

When the power supply voltage VDD is equal to or higher than the voltage value V1 and is lower than a voltage value V2, the resistance value CR1 is a combined resistance value R1//R2//R3 of the resistive elements 41, 42, and 43 which are connected in parallel. The voltage value V2 is higher than the voltage value V1. The voltage value V2 is a voltage value when the transistors 31 and 32 are both turned on. The absolute value of the voltage value V2 is, for example, the same as a sum of the absolute value of the threshold voltage of the transistor 31 and the absolute value of the threshold voltage of the transistor 32. Since the absolute value of the threshold voltage of the transistor 31 and the absolute value of the threshold voltage of the transistor 32 in the first embodiment are the same, the voltage value V2 is, for example, two times the voltage value V1. The combined resistance value R1//R2//R3 is lower than the resistance value R1.

When the power supply voltage VDD is equal to or higher than the voltage value V2, the resistance value CR1 is a combined resistance value R1//R2//R3//R4 of the resistive elements 41, 42, 43, and 44 which are connected in parallel. The combined resistance value R1//R2//R3//R4 is lower than the combined resistance value R1//R2//R3.

Even when the power supply voltage VDD becomes higher than the voltage value V2, the resistance value CR1 does not change. That is, in the first embodiment, the resistance value CR1 changes when the power supply voltage VDD is equal to or lower than the voltage value V2. The voltage value V2 is lower than a voltage value Vd of the power supply voltage VDD which is input to the semiconductor integrated circuit 100 when the semiconductor integrated circuit 100 operates. That is, the range of the power supply voltage VDD in which the resistance value CR1 between the control terminal 10C and the ground terminal 10G changes in the first embodiment is lower than the voltage value Vd of the power supply voltage VDD which is input at the time of operating.

As described above, in the first embodiment, the resistance value CR1 between the control terminal 10C and the ground terminal 10G can change among three different resistance values with a change of the power supply voltage VDD.

In the first embodiment, when a voltage value equal to or higher than 0 V and lower than the voltage value V1 corresponds to a “first voltage value,” a voltage value equal to or higher than the voltage value V1 and lower than the voltage value V2 and a voltage value equal to or higher than the voltage value V2 correspond to a “second voltage value” higher than the first voltage value. In this case, the resistance value CR1 (the resistance value R1) when the power supply voltage VDD is equal to or higher than 0 V and lower than the voltage value V1 corresponds to a “first resistance value.” In this case, the resistance value CR1 (the resistance value R1//R2//R3) when the power supply voltage VDD is equal to or higher than the voltage value V1 and lower than the voltage value V2 and the resistance value CR1 (resistance value R1//R2//R3//R4) when the power supply voltage VDD is equal to or higher than the voltage value V2 correspond to a “second resistance value” lower than the first resistance value.

When the voltage value equal to or higher than the voltage value V1 and lower than the voltage value V2 corresponds to the “first voltage value,” the voltage value equal to or higher than the voltage value V2 corresponds to the “second voltage value” higher than the first voltage value. In this case, the resistance value CR1 (resistance value R1//R2//R3) when the power supply voltage VDD is equal to or higher than the voltage value V1 and lower than the voltage value V2 corresponds to the “first resistance value.” In this case, the resistance value CR1 (resistance value R1//R2//R3//R4) when the power supply voltage VDD is equal to or higher than the voltage value V2 corresponds to the “second resistance value” lower than the first resistance value.

A change of a state of the switching circuit 20 when the resistance value CR1 switches will be described below. In the switching circuit 20 illustrated in FIG. 2, when the power supply voltage VDD is lower than the voltage value V1, both the transistor 31 and the transistor 32 which are connected in series between the power supply terminal 10D and the ground terminal 10G are in an OFF state. In this case, the transistor 33 of which the gate terminal is connected to the gate terminal of the transistor 31 and the transistor 35 of which the gate terminal is connected to the gate terminal of the transistor 32 are in the OFF state. When the transistor 33 is in the OFF state, the voltage of the drain terminal of the transistor 33 is the control voltage VCT that is applied to the control terminal 10C. Accordingly, the voltage of the gate terminal of the transistor 34 connected to the drain terminal of the transistor 33 is the control voltage VCT. Accordingly, the voltages applied to the gate terminal and the source terminal of the transistor 34 have the same value, and the transistor 34 is turned off. As a result, when the power supply voltage VDD is lower than the voltage value V1, all the transistors 31 to 35 are turned off. Accordingly, all of the transistor 33 provided between the resistive element 42 and the ground GND, the transistor 34 provided between the control terminal 10C and the resistive element 43, and the transistor 35 provided between the resistive element 44 and the ground GND are in a high-impedance state. Accordingly, connection between the control terminal 10C and the ground GND via the resistive elements 42, 43, and 44 is cut off. As a result, only the resistive element 41 is connected to serve as a resistor between the control terminal 10C and the ground terminal 10G, and the resistance value CR1 between the control terminal 10C and the ground terminal 10G is the resistance value R1.

In the switching circuit 20 illustrated in FIG. 2, when the power supply voltage VDD is equal to or higher than the voltage value V1 and lower than the voltage value V2, a voltage equal to or higher than a threshold voltage required for turning on the transistor 31 is applied to the source terminal of the transistor 31. In this case, electric charges flow from the source terminal to the drain terminal of the transistor 31, and the voltages of the drain terminal and the gate terminal of the transistor 31 increase. When the voltage of the gate terminal of the transistor 31 is equal to or higher than the voltage value V1, the voltage of the gate terminal of the transistor 33 is also equal to or higher than the voltage value V1, and the transistor 33 is turned on. Here, when the voltage of the gate terminal of the transistor 31 is equal to or higher than the voltage value V1, the voltage of the drain terminal of the transistor 31 is also equal to or higher than the voltage value V1, and thus the voltage of the source terminal of the transistor 32 is equal to or higher than the voltage value V1, and the transistor 32 is going to be turned on. However, when the power supply voltage VDD is lower than the voltage value V2, electric charges flow from the source terminal to the drain terminal of the transistor 32, thus the voltage of the source terminal of the transistor 32 decreases immediately, and thus the transistor 32 is turned off. In order to turn on the transistor 32, even when a current flows in the transistor 32 and the voltage of the source terminal of the transistor 32 decreases, the decreasing voltage of the source terminal needs to be greater by equal to or greater than the absolute value of the threshold voltage of the transistor 32 than the voltage of the drain terminal and the gate terminal of the transistor 32. Accordingly, until the power supply voltage VDD reaches the voltage value V2 which is the sum of the absolute value of the threshold voltage of the transistor 31 and the absolute value of the threshold voltage of the transistor 32, the voltages of the gate terminals of the transistors 31 and 33 are equal to or higher than the voltage value V1 capable of turning on the transistor 33, and the transistor 32 is turned off.

When the transistor 33 is turned on, the control terminal 10C is connected to the ground terminal 10G via the resistive element 42. When the transistor 33 is turned on, the on-resistance value of the transistor 33 is much lower than the resistance value R2 of the resistive element 42, and thus the voltage of the drain terminal of the transistor 33 becomes almost the same potential as the ground GND. Accordingly, the voltage of the gate terminal of the transistor 34 connected to the drain terminal of the transistor 33 becomes almost the same as the ground GND. Since the control voltage VCT equal to or higher than the absolute value of the threshold voltage of the transistor 34 is applied to the source terminal of the transistor 34, the transistor 34 is turned on. Accordingly, the control terminal 10C is connected to the ground terminal 10G via the resistive element 43. As a result, when the power supply voltage VDD is equal to or higher than the voltage value V1 and lower than the voltage value V2, the plurality of resistive elements 41, 42, and 43 are connected in parallel to serve as a resistor between the control terminal 10C and the ground terminal 10G. Accordingly, the resistance value CR1 between the control terminal 10C and the ground terminal 10G is a combined resistance value R1//R2//R3 of the resistance values R1, R2, and R3 of the resistive elements 41, 42, and 43 connected in parallel.

In the switching circuit 20 illustrated in FIG. 2, when the power supply voltage VDD is equal to or higher than the voltage value V2, both the transistor 31 and the transistor 32 are turned on. When the transistor 32 is turned on and electric charges flow from the source terminal to the drain terminal of the transistor 32, the voltage of the drain terminal and the gate terminal of the transistor 32 increases. When the voltage of the gate terminal of the transistor 32 is equal to or higher than the absolute value of the threshold voltage, the transistor 35 of which the gate terminal is connected to the gate terminal of the transistor 32 is turned on. When the transistor 35 is turned on, the control terminal 10C is connected to the ground terminal 10G via the resistive element 44. Accordingly, when the power supply voltage VDD is equal to or higher than the voltage value V2, the plurality of resistive elements 41, 42, 43, and 44 are connected in parallel to serve as a resistor between the control terminal 10C and the ground terminal 10G. As a result, the resistance value CR1 between the control terminal 10C and the ground terminal 10G is the combined resistance value R1//R2//R3//R4 of the resistance values R1, R2, R3, and R4 of the resistive elements 41, 42, 43, and 44 connected in parallel.

As described above, in the first embodiment, when the power supply voltage VDD changes, the state of the switching circuit 20 switches, and the combination of the resistive elements serving as a resistor between the control terminal 10C and the ground terminal 10G changes. Specifically, when the power supply voltage VDD is equal to or higher than 0 V and lower than the voltage value V1, the resistive element 41 is the resistive element serving as a resistor between the control terminal 10C and the ground terminal 10G. When the power supply voltage VDD is equal to or higher than the voltage value V1 and lower than the voltage value V2, the resistive element 41, the resistive element 42, and the resistive element 43 are the resistive elements serving as a resistor between the control terminal 10C and the ground terminal 10G. When the power supply voltage VDD is equal to or higher than the voltage value V2, the resistive element 41, the resistive element 42, the resistive element 43, and the resistive element 44 are the resistive elements serving as a resistor between the control terminal 10C and the ground terminal 10G.

According to the first embodiment, the semiconductor integrated circuit 100 includes the control terminal 10C (a first terminal) and the ground terminal 10G (a second terminal). When the power supply voltage VDD (an input voltage) which is externally input changes, the resistance value CR1 between the control terminal 10C and the ground terminal 10G changes. Accordingly, when the power supply voltage VDD which is externally input to the semiconductor integrated circuit 100 is changed, the value of a current flowing between the control terminal 10C and the ground terminal 10G can be changed. Accordingly, it is possible to set characteristics of a current value which is output when the power supply voltage VDD is externally input to the semiconductor integrated circuit 100 to different characteristics for different semiconductor integrated circuits and to provide differences to the characteristics of the semiconductor integrated circuits 100. Accordingly, by determining the value of the current flowing between the control terminal 10C and the ground terminal 10G in response to the power supply voltage VDD, it is possible to easily discriminate between the semiconductor integrated circuits 100s. For example, the characteristics of a change of the resistance value CR1 with respect to the power supply voltage VDD in a plurality of types of semiconductor integrated circuits 100 which are to be externally discriminated between are made to be different. Accordingly, the value of the current flowing between the control terminal 10C and the ground terminal 10G in various semiconductor integrated circuits 100 can be made to be different by inputting predetermined values of the power supply voltage VDD to the plurality of types of semiconductor integrated circuits 100. As a result, by ascertaining a relationship between the power supply voltage VDD input to the semiconductor integrated circuits 100 and a current value output therefrom in advance, it is possible to easily discriminate between the types of the semiconductor integrated circuits 100 from the output current value. In this way, in the first embodiment, it is possible to provide a difference to the characteristics of the semiconductor integrated circuits 100 by giving the characteristics of a change of the resistance value CR1 between the control terminal 10C and the ground terminal 10G to the semiconductor integrated circuits 100.

For example, when a semiconductor integrated circuit according to a comparative example in which the resistance value CR1 is constant regardless of the value of the power supply voltage VDD is assumed as indicated by a two-dot chain line in FIG. 3, the resistance value CR1 is a low value which is the same as the combined resistance value R1//R2//R3//R4 even if the power supply voltage VDD lower than the voltage value V1 is input to the semiconductor integrated circuit according to the comparative example. On the other hand, in the semiconductor integrated circuit 100 according to the first embodiment, when the power supply voltage VDD lower than the voltage value V1 is input, the resistance value CR1 is the resistance value R1 which is higher than the combined resistance value R1//R2//R3//R4. Accordingly, when the power supply voltage VDD lower than the voltage value V1 is added to the semiconductor integrated circuit 100 according to the first embodiment and the semiconductor integrated circuit according to the comparative example, the value of the current flowing between the control terminal 10C and the ground terminal 10G in the semiconductor integrated circuit 100 according to the first embodiment is smaller than that in the semiconductor integrated circuit according to the comparative example. As a result, when the value of the current flowing between the control terminal 10C and the ground terminal 10G in the semiconductor integrated circuit 100 according to the first embodiment is smaller and the value of the current flowing between the control terminal 10C and the ground terminal 10G in the semiconductor integrated circuit according to the comparative example is larger, it is possible to easily discriminate between them.

According to the first embodiment, the range of the power supply voltage VDD (the input voltage) in which the resistance value CR1 between the control terminal 10C (the first terminal) and the ground terminal 10G (the second terminal) changes is lower than the voltage value Vd of the power supply voltage VDD at the time of operating. Accordingly, when the semiconductor integrated circuit 100 operates, it is possible to curb a change of the resistance value CR1 between the control terminal 10C and the ground terminal 10G. Accordingly, it is possible to curb an influence of the change of the resistance value CR1 on the operation of the semiconductor integrated circuit 100.

According to the first embodiment, when the power supply voltage VDD (the input voltage) is a first voltage value equal to or higher than 0 V and lower than the voltage value V1, the resistance value CR1 between the control terminal 10C (the first terminal) and the ground terminal 10G (the second terminal) is the resistance value R1 (the first resistance value). When the power supply voltage VDD is a second voltage value higher than the first voltage value, that is, when the power supply voltage VDD is equal to or higher than the voltage value V1 and lower than the voltage value V2, the resistance value CR1 between the control terminal 10C and the ground terminal 10G is the combined resistance value R1//R2//R3 (the second resistance value) lower than the resistance value R1. Accordingly, when the power supply voltage VDD is low, the resistance value CR1 can be increased. As a result, when the semiconductor integrated circuits 100 are discriminated between, it is possible to discriminate between the semiconductor integrated circuits 100 without increasing the power supply voltage VDD.

According to the first embodiment, when the power supply voltage VDD (the input voltage) changes, the resistance value CR1 between the control terminal 10C (the first terminal) and the ground terminal 10G (the second terminal) can change among three different resistance values. Accordingly, by adjusting the resistance values of the resistive elements 41 to 44 to adjust the three resistance values CR1, it is possible to provide larger differences to the characteristics of the semiconductor integrated circuits 100. As a result, it is possible to more easily discriminate between the semiconductor integrated circuits 100.

According to the first embodiment, the semiconductor integrated circuit 100 includes the switching circuit 20 provided between the control terminal 10C and the ground terminal 10G. The switching circuit 20 includes a plurality of transistors and a plurality of resistive elements. When the power supply voltage VDD (the input voltage) changes, the state of the switching circuit 20 changes, and a combination of the resistive elements serving as a resistor between the control terminal 10C and the ground terminal 10G changes. Accordingly, it is possible to easily change the resistance value CR1 between the control terminal 10C and the ground terminal 10G according to the magnitude of the power supply voltage VDD.

According to the first embodiment, the plurality of transistors included in the switching circuit 20 include the transistors 31 and 32 (the first transistor) provided between the power supply terminal 10D to which the power supply voltage VDD (the input voltage) is applied and the ground terminal 10G. The transistors 31 and 32 are diode-connected. Accordingly, the ON/OFF states of the transistors 31 and 32 are switched according to the magnitude of the power supply voltage VDD applied to the power supply terminal 10D. As a result, it is possible to easily switch the state of the switching circuit 20 according to the magnitude of the power supply voltage VDD.

According to the first embodiment, the plurality of transistors included in the switching circuit 20 include a plurality of transistors 31 and 32 (the first transistor) which are provided between the power supply terminal 10D and the ground terminal 10G and which are diode-connected. The plurality of transistors 31 and 32 are connected in series. Accordingly, as described above, the states of the plurality of transistors 31 and 32 can be sequentially switched as increasing the power supply voltage VDD. As a result, it is possible to switch the state of the switching circuit 20 in a stepwise manner a plurality of times and to change the resistance value CR1 between the control terminal 10C and the ground terminal 10G in three or more steps. Accordingly, it is possible to provide larger differences to the characteristics of the semiconductor integrated circuit 100.

According to the first embodiment, the plurality of resistive elements included in the switching circuit 20 include the resistive element 41 which is connected between the control terminal 10C and the ground terminal 10G without using a transistor. Accordingly, the resistive element 41 always serves as a resistor between the control terminal 10C and the ground terminal 10G. As a result, it is possible to connect the control terminal 10C to the ground GND even when the power supply voltage VDD has any value.

According to the first embodiment, the plurality of transistors included in the switching circuit 20 include the transistors 33, 34, and 35 (the second transistor) which are provided between the control terminal 10C and the ground terminal 10G. The plurality of resistive elements included in the switching circuit 20 include the resistive elements 42, 43, and 44 which are connected in series to the transistors 33, 34, and 35 between the control terminal 10C and the ground terminal 10G. Accordingly, when the states of the transistors 33, 34, and 35 switch between the ON state and the OFF state, switching between a state in which the resistive elements 42, 43, and 44 serve as a resistor between the control terminal 10C and the ground terminal 10G and a state in which the resistive elements 42, 43, and 44 do not serve as a resistor between the control terminal 10C and the ground terminal 10G, that is, an open state, is carried out. As a result, it is possible to easily change the resistance value CR1 between the control terminal 10C and the ground terminal 10G.

According to the first embodiment, the semiconductor integrated circuit 100 includes the power supply terminal 10D which is the third terminal. The power supply terminal 10D is a terminal to which the power supply voltage VDD which is the input voltage is applied. Accordingly, the terminal to which the power supply voltage VDD is input can be set to a terminal other than the control terminal 10C and the ground terminal 10G. As a result, by keeping the control voltage VCT applied to the control terminal 10C constant, the current value flowing between the control terminal 10C and the ground terminal 10G can be made to be constant regardless of the power supply voltage VDD when the resistance value CR1 between the control terminal 10C and the ground terminal 10G is constant. Accordingly, it is possible to more easily discriminate between the semiconductor integrated circuits 100 by detecting the current value flowing between the control terminal 10C and the ground terminal 10G.

### Second Embodiment

A second embodiment is different from the first embodiment in a configuration of a switching circuit 220. In the following description, the same elements as in the aforementioned embodiment may be referred to by the same reference signs and description thereof may be omitted.

FIG. 4 is a circuit diagram illustrating a semiconductor integrated circuit 200 according to the second embodiment. As illustrated in FIG. 4, the semiconductor integrated circuit 200 includes a power supply terminal 210D, a control terminal 210C, and a ground terminal 10G. In the second embodiment, the power supply terminal 210D corresponds to a “first terminal,” and the control terminal 210C corresponds to a “second terminal.”

A switching circuit 220 includes a plurality of transistors 31, 32, 233, 234, 235, and 236 and a plurality of resistive elements 241, 242, 243, 244, 45, and 246. The transistor 233 is the same as the transistor 33 in the first embodiment except that the drain terminal thereof is connected to the power supply terminal 210D via the resistive element 244. The transistor 235 is the same as the transistor 35 in the first embodiment except that the drain terminal thereof is connected to the power supply terminal 210D via the resistive element 246.

The transistors 234 and 236 are provided between the power supply terminal 210D and the control terminal 210C. The transistors 234 and 236 in the second embodiment correspond to a “second transistor.” The transistors 234 and 236 are field effect transistors. More specifically, the transistors 234 and 236 are P-channel MOSFETs. The source terminal of the transistor 234 is connected to the power supply terminal 210D. The drain terminal of the transistor 234 is connected to the control terminal 210C via the resistive element 242. The gate terminal of the transistor 234 is connected to the drain terminal of the transistor 233. The source terminal of the transistor 236 is connected to the power supply terminal 210D. The drain terminal of the transistor 236 is connected to the control terminal 210C via the resistive element 243.

It is assumed that the absolute values of the threshold voltages of the transistors 31 to 236 are the same. The absolute values of the threshold voltages of the transistors 31 to 236 may be different from each other. The on-resistance values of the transistors 234 and 236 are much smaller than the resistance values of the resistive elements 242 and 243. The on-resistance values of the transistors 234 and 236 are, for example, equal to or less than 1/several hundreds of the resistance values of the resistive elements 242 and 243. The on-resistance values of the transistors 234 and 236 are not particularly limited.

The resistive elements 241, 242, and 243 are provided between the power supply terminal 210D and control terminal 210C. One end of the resistive element 241 is connected to the power supply terminal 210D. The other end of the resistive element 241 is connected to the control terminal 210C. The resistive element 241 is a resistive element connected between the power supply terminal 210D which is the first terminal and the control terminal 210C which is the second terminal without using a transistor. One end of the resistive element 242 is connected to the drain terminal of the transistor 234. The other end of the resistive element 242 is connected to the control terminal 210C. One end of the resistive element 243 is connected to the drain terminal of the transistor 236. The other end of the resistive element 243 is connected to the control terminal 210C. The resistive elements 242 and 243 are resistive elements connected in series to the transistors 234 and 236, respectively, between the power supply terminal 210D and the control terminal 210C.

The resistive elements 244 and 246 are provided between the power supply terminal 210D and the ground terminal 10G. One end of the resistive element 244 is connected to the power supply terminal 210D. The other end of the resistive element 244 is connected to the drain terminal of the transistor 233. One end of the resistive element 246 is connected to the power supply terminal 210D. The other end of the resistive element 246 is connected to the drain terminal of the transistor 235.

The resistive elements 241, 242, and 243 in the second embodiment are resistive elements capable of serving as a resistor between the power supply terminal 210D which is the first terminal and the control terminal 210C which is the second terminal. In the second embodiment, when the power supply voltage VDD which is the input voltage changes, the state of the switching circuit 220 switches, and a combination of the resistive elements 241 to 243 serving as a resistor between the power supply terminal 210D and the control terminal 210C changes. Accordingly, when the power supply voltage VDD which is externally input changes, a resistance value CR2 between the power supply terminal 210D and the control terminal 210C changes.

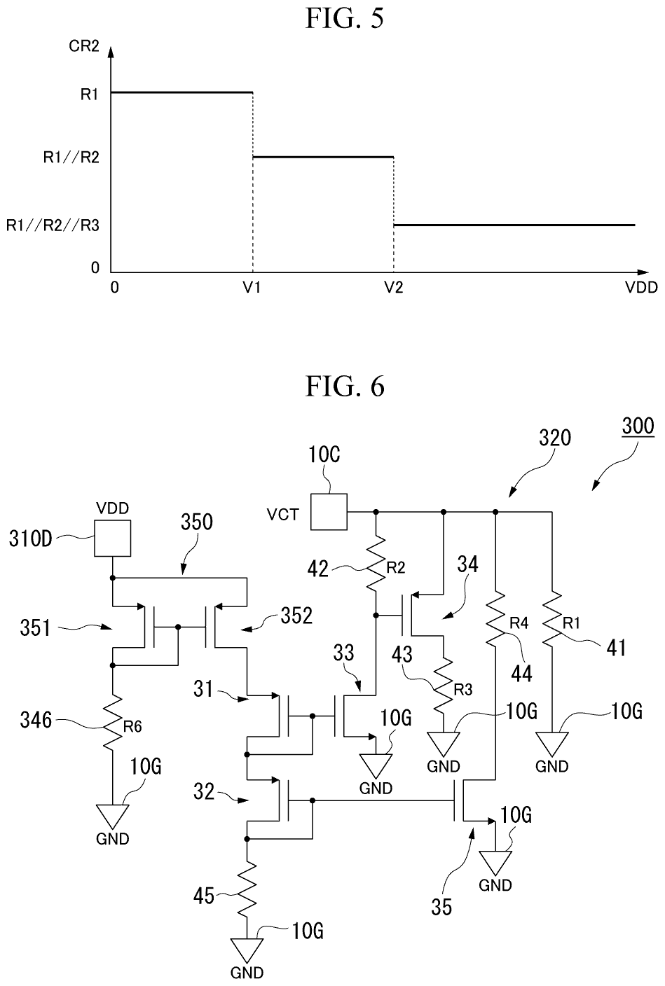

FIG. 5 is a graph illustrating an example of a change of the resistance value CR2 between the power supply terminal 210D and the control terminal 210C. In FIG. 5, the horizontal axis represents the power supply voltage VDD, and the vertical axis represents the resistance value CR2 between the power supply terminal 210D and the control terminal 210C. In FIGS. 4 and 5, R1 denotes the resistance value of the resistive element 241, R2 denotes the resistance value of the resistive element 242, and R3 denotes the resistance value of the resistive element 243. In the example illustrated in FIG. 5, the control voltage VCT applied to the control terminal 210C is equal to or lower than the power supply voltage VDD applied to the power supply terminal 210D.

As illustrated in FIG. 5, when the power supply voltage VDD is equal to or higher than 0 V and lower than the voltage value V1, the resistance value CR2 is the resistance value R1 of the resistive element 241. When the power supply voltage VDD is equal to or higher than the voltage value V1 and lower than the voltage value V2, the resistance value CR2 is a combined resistance value R1//R2 of the resistive elements 241 and 242 connected in parallel. The combined resistance value R1//R2 is lower than the resistance value R1. When the power supply voltage VDD is equal to or higher than the voltage value V2, the resistance value CR2 is a combined resistance value R1//R2//R3 of the resistive elements 241, 242, and 243 connected in parallel. The combined resistance value R1//R2//R3 is lower than the combined resistance value R1//R2. Even when the power supply voltage VDD is higher than the voltage value V2, the resistance value CR2 does not change. That is, in the second embodiment, the resistance value CR2 changes when the power supply voltage VDD is equal to or lower than the voltage value V2.

In the second embodiment, when the resistance value R1 corresponds to the “first resistance value,” the combined resistance value R1//R2 and the combined resistance value R1//R2//R3 correspond to the “second resistance value.” When the combined resistance value R1//R2 corresponds to the “first resistance value,” the combined resistance value R1//R2//R3 corresponds to the “second resistance value.”

A change of the state of the switching circuit 220 when the resistance value CR2 changes will be described below. In the switching circuit 220 illustrated in FIG. 4, when the power supply voltage VDD is lower than the voltage value V1, the transistors 31, 32, 233, 234, and 235 are in the OFF state similarly to the first embodiment. When the transistor 235 is in the OFF state, the voltage of the drain terminal of the transistor 235 is the power supply voltage VDD applied to the power supply terminal 210D. Accordingly, the voltage of the gate terminal of the transistor 236 connected to the drain terminal of the transistor 235 is the power supply voltage VDD. Therefore, the voltages applied to the gate terminal and the source terminal of the transistor 236 are the same value, and the transistor 236 is turned off. As a result, when the power supply voltage VDD is lower than the voltage value V1, all of the transistors 31 to 236 are turned off. Accordingly, only the resistive element 241 is connected to serve as a resistor between the power supply terminal 210D and the control terminal 210C, and the resistance value CR2 between the power supply terminal 210D and the control terminal 210C is the resistance value R1.

In the switching circuit 220 illustrated in FIG. 4, when the power supply voltage VDD is equal to or higher than the voltage value V1 and lower than the voltage value V2, a voltage equal to or higher than the threshold voltage required for turning on the transistor 31 is applied to the source terminal of the transistor 31. Accordingly, similarly to the first embodiment, the transistor 233 and the transistor 234 are turned on. On the other hand, the transistors 32, 235, and 236 are maintained in the OFF state. Accordingly, the resistive element 241 and the resistive element 242 are connected in parallel to serve as a resistor between the power supply terminal 210D and the control terminal 210C. As a result, when the power supply voltage VDD is equal to or higher than the voltage value V1 and lower than the voltage value V2, the resistance value CR2 between the power supply terminal 210D and the control terminal 210C is the combined resistance value R1//R2 of the resistance values R1 and R2 of the resistive elements 241 and 242 connected in parallel.

In the switching circuit 220 illustrated in FIG. 4, when the power supply voltage VDD is equal to or higher than the voltage value V2, the transistor 32 is turned on similarly to the first embodiment. Accordingly, similarly to the first embodiment, the transistors 31, 32, 233, 234, and 235 are turned on. When the transistor 235 is turned on, the voltage of the drain terminal of the transistor 235 is almost the same potential as the ground GND. Accordingly, the voltage of the gate terminal of the transistor 236 connected to the drain terminal of the transistor 235 is almost the same potential as the ground GND. Since the power supply voltage VDD is applied to the source terminal of the transistor 236, the transistor 236 is turned on. When the transistor 236 is turned on, the power supply terminal 210D is connected to the control terminal 210C via the resistive element 243. Accordingly, when the power supply voltage VDD is equal to or higher than the voltage value V2, the plurality of resistive elements 241, 242, and 243 are connected in parallel to serve as a resistor between the power supply terminal 210D and the control terminal 210C. As a result, the resistance value CR2 between the power supply terminal 210D and the control terminal 210C is the combined resistance value R1//R2//R3 of the resistance values R1, R2, and R3 of the resistive elements 241, 242, and 243.

The other configuration and operations of the switching circuit 220 are the same as the configuration and operations of the switching circuit 20 according to the first embodiment. The other configuration and operations of the semiconductor integrated circuit 200 are the same as the other configuration and operations of the semiconductor integrated circuit 100 according to the first embodiment.

According to the second embodiment, the power supply terminal 210D which is the first terminal is a terminal to which the power supply voltage VDD which is an input voltage is applied. Accordingly, the terminal to which the input voltage is applied and one terminal for detecting a current based on a change of the resistance value CR2 can share the same terminal. As a result, it is possible to perform a test for discriminating the semiconductor integrated circuit 200 using only two terminals. Accordingly, it is possible to more easily discriminate between the semiconductor integrated circuits 200.

### Third Embodiment

A third embodiment is different from the first embodiment in a configuration of a switching circuit 320. In the following description, the same elements as in the aforementioned embodiments may be appropriately referred to by the same reference signs and description thereof may be omitted.

FIG. 6 is a circuit diagram illustrating a semiconductor integrated circuit 300 according to the third embodiment. As illustrated in FIG. 6, the switching circuit 320 of the semiconductor integrated circuit 300 includes a current source circuit 350. The current source circuit 350 includes a pair of transistors 351 and 352. The pair of transistors 351 and 352 is field effect transistors. More specifically, the pair of transistors 351 and 352 is P-channel MOSFETs. The pair of transistors 351 and 352 constitutes a current mirror circuit. The source terminal of the transistor 351 and the source terminal of the transistor 352 are connected to each other. The source terminal of the transistor 351 and the source terminal of the transistor 352 are connected to a power supply terminal 310D. The power supply terminal 310D is the same as the power supply terminal 10D in the first embodiment except that it is connected to the source terminal of the transistor 31 via the current source circuit 350.

The drain terminal of the transistor 351 is connected to the ground GND via a resistive element 346. The drain terminal of the transistor 351 is connected to the gate terminal of the transistor 351. The drain terminal of the transistor 352 is connected to the source terminal of the transistor 31. The gate terminal of the transistor 352 is connected to the gate terminal of the transistor 351.

When the power supply voltage VDD applied to the power supply terminal 310D increases and the transistor 351 is turned on, a current Id flows from the power supply terminal 310D to the ground GND via the transistor 351. The current Id is expressed by Id=(VDD−Vth)/R6. Vth denotes the absolute value of a threshold voltage of the transistor 351. R6 denotes a resistance value of the resistive element 346. Since the pair of transistors 351 and 352 constitutes a current mirror circuit, a current corresponding to a size ratio of the transistor 351 and the transistor 352 also flows in the transistor 352 when the current Id flows in the transistor 351. When a current flows in the transistor 352, the voltage of the source terminal of the transistor 31 increases. Accordingly, a voltage can be applied to the source terminal of the transistor 31 via the current source circuit 350.

The other configuration and operations of the switching circuit 320 are the same as the configuration and operations of the switching circuit 20 according to the first embodiment. The other configuration and operations of the semiconductor integrated circuit 300 are the same as the other configuration and operations of the semiconductor integrated circuit 100 according to the first embodiment.

### Fourth Embodiment

A fourth embodiment is different from the first embodiment in a configuration of a switching circuit 420. In the following description, the same elements as in the aforementioned embodiments may be appropriately referred to by the same reference signs and description thereof may be omitted.

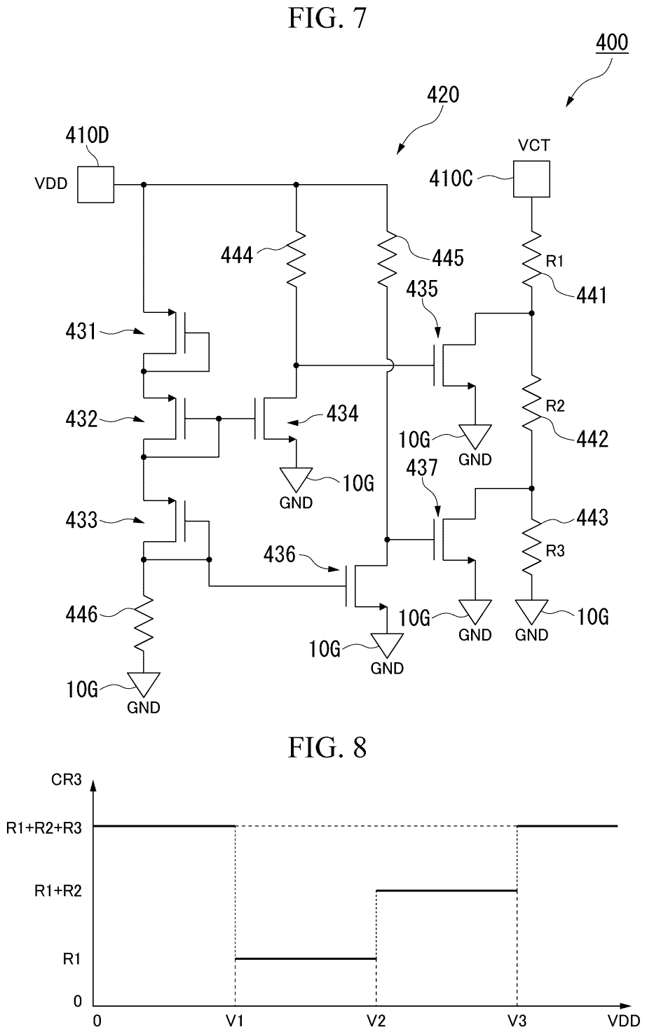

FIG. 7 is a circuit diagram illustrating a semiconductor integrated circuit 400 according to the fourth embodiment. As illustrated in FIG. 7, the switching circuit 420 of the semiconductor integrated circuit 400 includes a plurality of transistors 431 to 437 and a plurality of resistive elements 441 to 446. The plurality of transistors 431 to 437 are field effect transistors. The plurality of transistors 431, 432, and 433 are P-channel MOSFETs. The plurality of transistors 434, 435, 436, and 437 are N-channel MOSFETs.

The plurality of transistors 431, 432, and 433 correspond to a “first transistor” which is provided between a power supply terminal 410D and the ground terminal 10G. Each of the plurality of transistors 431, 432, and 433 is diode-connected. The transistor 431, the transistor 432, and the transistor 433 are connected in series. The source terminal of the transistor 431 is connected to the power supply terminal 410D. The drain terminal of the transistor 431 is connected to the gate terminal of the transistor 431 and the source terminal of the transistor 432. The drain terminal of the transistor 432 is connected to the gate terminal of the transistor 432 and the source terminal of the transistor 433. The drain terminal of the transistor 433 is connected to the gate terminal of the transistor 433. The drain terminal of the transistor 433 is connected to the ground GND via the resistive element 446.

The transistors 434 and 436 are provided between the power supply terminal 410D and the ground terminal 10G. The drain terminal of the transistor 434 is connected to the power supply terminal 410D via the resistive element 444. The source terminal of the transistor 434 is connected to the ground GND. The gate terminal of the transistor 434 is connected to the gate terminal of the transistor 432. The drain terminal of the transistor 436 is connected to the power supply terminal 410D via the resistive element 445. The source terminal of the transistor 436 is connected to the ground GND. The gate terminal of the transistor 436 is connected to the gate terminal of the transistor 433.

The transistors 435 and 437 in the fourth embodiment correspond to a “second transistor” which is provided between the power supply terminal 410C and the ground terminal 10G. The drain terminal of the transistor 435 is connected to the control terminal 410C via the resistive element 441. The source terminal of the transistor 435 is connected to the ground GND. The gate terminal of the transistor 435 is connected to the drain terminal of the transistor 434. The drain terminal of the transistor 437 is connected to the control terminal 410C via the resistive elements 441 and 442. The source terminal of the transistor 437 is connected to the ground GND. The gate terminal of the transistor 437 is connected to the drain terminal of the transistor 436.

It is assumed that the absolute values of threshold voltages of the transistors 431 to 437 are the same. The absolute values of the threshold voltages of the transistors 431 to 437 may be different from each other. On-resistance values of the transistors 435 and 437 are much smaller than resistance values of the resistive elements 441, 442, and 443. The on-resistance values of the transistors 435 and 437 are equal to or less than, for example, 1/several hundreds of the resistance values of the resistive elements 441, 442, and 443. The on-resistance values of the transistors 435 and 437 are not particularly limited.

The resistive element 441 is connected in series to the transistor 435 between the control terminal 410C and the ground terminal 10G. The resistive element 441 and the resistive element 442 are connected in series to the transistor 437 between the control terminal 410C and the ground terminal 10G. The resistive element 441, the resistive element 442, and the resistive element 443 are connected in series between the control terminal 410C and the ground terminal 10G without using a transistor.

One end of the resistive element 441 is connected to the control terminal 410C. The other end of the resistive element 441 is connected to the drain terminal of the transistor 435 and one end of the resistive element 442. The other end of the resistive element 442 is connected to the drain terminal of the transistor 437 and one end of the resistive element 443. The other end of the resistive element 443 is connected to the ground GND.

The other configuration of the power supply terminal 410D is the same as the other configuration of the power supply terminal 10D in the first embodiment. The other configuration of the control terminal 410C is the same as the other configuration of the control terminal 10C in the first embodiment. In the fourth embodiment, the power supply terminal 410D corresponds to a “third terminal,” and the control terminal 410C corresponds to a “first terminal.”

The resistive elements 441, 442, and 443 in the fourth embodiment are resistive elements capable of serving as a resistor between the control terminal 410C which is the first terminal and the ground terminal 10G which is the second terminal. In the fourth embodiment, when the power supply voltage VDD which is an input voltage changes, a state of the switching circuit 420 switches, and a combination of the resistive elements 441 to 443 serving as a resistor between the control terminal 410C and the ground terminal 10G changes. Accordingly, when the power supply voltage VDD which is externally input changes, a resistance value CR3 between the control terminal 410C and the ground terminal 10G changes.

FIG. 8 is a graph illustrating an example of a change of the resistance value CR3 between the control terminal 410C and the ground terminal 10G. In FIG. 8, the horizontal axis represents the power supply voltage VDD, and the vertical axis represents the resistance value CR3 between the control terminal 410C and the ground terminal 10G. In FIGS. 7 and 8, R1 denotes the resistance value of the resistive element 441, R2 denotes the resistance value of the resistive element 442, and R3 denotes the resistance value of the resistive element 443.

As illustrated in FIG. 8, when the power supply voltage VDD is equal to or higher than 0 V and lower than the voltage value V1, the resistance value CR3 is a combined resistance value R1+R2+R3 of the resistive elements 441, 442, and 443 connected in series. The voltage value V1 is, for example, equal to the absolute value of the threshold voltage of the transistors 435 and 437. When the power supply voltage VDD is equal to or higher than the voltage value V1 and lower than the voltage value V2, the resistance value CR3 is the resistance value R1 of the resistive element 441. The resistance value R1 is smaller than the combined resistance value R1+R2+R3. The voltage value V2 is higher than the voltage value V1. The voltage value V2 is, for example, equal to a sum of the absolute value of the threshold voltage of the transistor 431 and the absolute value of the threshold voltage of the transistor 432. Since the absolute values of the threshold voltages of the transistors in the fourth embodiment are the same, the voltage value V2 is two times the voltage value V1.

When the power supply voltage VDD is equal to or higher than the voltage value V2 and lower than the voltage value V3, the resistance value CR3 is a combined resistance value R1+R2 of the resistive elements 441 and 442 connected in series. The combined resistance value R1+R2 is higher than the resistance value R1 and lower than the combined resistance value R1+R2+R3. The voltage value V3 is higher than the voltage value V2. The voltage value V3 is equal to, for example, a sum of the absolute value of the threshold voltage of the transistor 431, the absolute value of the threshold voltage of the transistor 432, and the absolute value of the threshold voltage of the transistor 433. In the fourth embodiment, since the absolute values of the threshold voltages of the transistors are the same, the voltage value V3 is three times the voltage value V1.

When the power supply voltage VDD is equal to or higher than the voltage value V3, the resistance value CR3 is the combined resistance value R1+R2+R3 of the resistive elements 441, 442, and 443 connected in series. Even when the power supply voltage VDD is higher than the voltage value V3, the resistance value CR3 does not change. That is, in the fourth embodiment, the resistance value CR3 changes when the power supply voltage VDD is equal to or lower than the voltage value V3.

When a voltage equal to or higher than the voltage value V1 and lower than the voltage value V2 corresponds to a “third voltage value,” a voltage value equal to or higher than the voltage value V2 and lower than the voltage value V3 and a voltage value equal to or higher than the voltage value V3 corresponds to a “fourth voltage value.” In this case, the resistance value CR3 (the resistance value R1) when the power supply voltage VDD is equal to or higher than the voltage value V1 and lower than the voltage value V2 corresponds to a “third resistance value.” In this case, the resistance value CR3 (the resistance value R1+R2) when the power supply voltage VDD is equal to or higher than the voltage value V2 and lower than the voltage value V3 and the resistance value CR3 (the resistance value R1+R2+R3) when the power supply voltage VDD is equal to or higher than the voltage value V3 corresponds to a “fourth resistance value” which is higher than the third resistance value.

When a voltage value equal to or higher than the voltage value V2 and lower than the voltage value V3 corresponds to the “third voltage value,” a voltage value equal to or higher than the voltage value V3 corresponds to the “fourth voltage value.” In this case, the resistance value CR3 (the resistance value R1+R2) when the power supply voltage VDD is equal to or higher than the voltage value V2 and lower than the voltage value V3 corresponds to the “third resistance value.” In this case, the resistance value CR3 (the resistance value R1+R2+R3) when the power supply voltage VDD is equal to or higher than the voltage value V3 corresponds to the “fourth resistance value” which is higher than the third resistance value.

A change of a state of the switching circuit 320 when the resistance value CR3 switches will be described below. In the switching circuit 320 illustrated in FIG. 7, when the power supply voltage VDD is lower than the voltage value V1, the transistors 431, 432, and 433 are in the OFF state similarly to the first embodiment. In this case, the transistor 434 of which the gate terminal is connected to the gate terminal of the transistor 432 and the transistor 436 of which the gate terminal is connected to the gate terminal of the transistor 433 are also in the OFF state.

The gate terminals of the transistors 435 and 437 are connected to the power supply terminal 410D via the resistive elements 444 and 445, respectively. Accordingly, the power supply voltage VDD is applied to the gate terminals of the transistors 435 and 437. However, when the power supply voltage VDD is lower than the voltage value V1 which is equal to the absolute values of the threshold voltages of the transistors 435 and 437, the transistors 435 and 437 are turned off. In this case, three resistive elements 441, 442, and 443 are connected in series to serve as a resistor between the control terminal 410C and the ground terminal 10G. Accordingly, when the power supply voltage VDD is lower than the voltage value V1, the resistance value CR3 between the control terminal 410C and the ground terminal 10G is the combined resistance value R1+R2+R3.

When the power supply voltage VDD is equal to or higher than the voltage value V1 and lower than the voltage value V2, a voltage equal to or higher than the threshold voltage of the transistor 431 is applied to the source terminal of the transistor 431, but the transistor 432 cannot be turned on with a voltage value lower than the voltage value V2 which is two times the absolute value of the threshold voltage. Accordingly, the transistors 432 and 433 are maintained in the OFF state. On the other hand, since the power supply voltage VDD applied to the gate terminals of the transistors 435 and 437 is equal to or higher than the absolute values of the threshold voltages of the transistors 435 and 437, the transistors 435 and 437 are turned on. When the transistor 435 is turned on, the control terminal 410C and the ground terminal 10G are connected via the resistive element 441 and the transistor 435. When the transistor 437 is turned on, the control terminal 410C and the ground terminal 10G are connected via the resistive element 441, the resistive element 442, and the transistor 437. In this case, a current flowing from the control terminal 410C to the ground terminal 10G flows along a path passing through the resistive element 441 and the transistor 435 in which a resistance value is lower than that in other paths. Accordingly, only the resistive element 441 can be considered to be connected between the control terminal 410C and the ground terminal 10G. As a result, when the power supply voltage VDD is equal to or higher than the voltage value V1 and lower than the voltage value V2, the resistance value CR3 between the control terminal 410C and the ground terminal 10G is the resistance value R1.

When the power supply voltage VDD is equal to or higher than the voltage value V2 and lower than the voltage value V3, that is, when the power supply voltage VDD is equal to or higher than two times the absolute value of the threshold voltage and lower than three times, the transistor 431 and the transistor 432 are turned on, and the voltages of the drain terminal and the gate terminal of the transistor 432 increase. Accordingly, the transistor 434 of which the gate terminal is connected to the gate terminal of the transistor 432 is turned on. When the transistor 434 is turned on, the voltage of the drain terminal of the transistor 434 is almost the potential of the ground GND. Accordingly, the transistor 435 of which the gate terminal is connected to the drain terminal of the transistor 434 is turned off. On the other hand, when the power supply voltage VDD is equal to or higher than the voltage value V2 and lower than the voltage value V3, the power supply voltage VDD has not reached a voltage value for turning on the transistor 433 and the transistor 433 is maintained in the OFF state. Accordingly, the transistor 436 of which the gate terminal is connected to the gate terminal of the transistor 433 is also maintained in the OFF state. As a result, the transistor 437 is maintained in the ON state. Accordingly, when the power supply voltage VDD is equal to or higher than the voltage value V2 and lower than the voltage value V3, a path extending from the control terminal 410C to the ground terminal 10G via the resistive element 441 and the transistor 435 has high impedance, and the control terminal 410C and the ground terminal 10G are connected via the resistive elements 441 and 442 and the transistor 437. As a result, when the power supply voltage VDD is equal to or higher than the voltage value V2 and lower than the voltage value V3, the resistance value CR3 between the control terminal 410C and the ground terminal 10G is the combined resistance value R1+R2 of two resistive elements 441 and 442.

When the power supply voltage VDD is equal to or higher than the voltage value V3, that is, when the power supply voltage VDD is equal to or higher than three times the absolute value of the threshold voltage, the transistor 431, the transistor 432, and the transistor 433 are turned on. Accordingly, the transistor 434 of which the gate terminal is connected to the gate terminal of the transistor 432 and the transistor 436 of which the gate terminal is connected to the gate terminal of the transistor 433 are also turned on. When the transistor 436 is turned on, the voltage of the drain terminal of the transistor 436 is almost the potential of the ground GND. Accordingly, the transistor 437 of which the gate terminal is connected to the drain terminal of the transistor 436 is turned off. Therefore, a path from the control terminal 410C to the ground terminal 10G via the resistive element 441 and the transistor 435 and a path from the control terminal 410C to the ground terminal 10G via the resistive elements 441 and 442 and the transistor 437 have high impedance. Accordingly, a current flows along a path from the control terminal 410C to the ground terminal 10G via the resistive elements 441, 442, and 443. As a result, when the power supply voltage VDD is equal to or higher than the voltage value V3, the resistance value CR3 between the control terminal 410C and the ground terminal 10G is the combined resistance value R1+R2+R3 of the resistive elements 441, 442, and 443.

The other configuration and operations of the switching circuit 420 are the same as the configuration and operations of the switching circuit 20 according to the first embodiment. The other configuration and operations of the semiconductor integrated circuit 400 are the same as the other configuration and operations of the semiconductor integrated circuit 100 according to the first embodiment.

According to the fourth embodiment, when the power supply voltage VDD (the input voltage) is a third voltage value which is equal to or higher than the voltage value V1 and lower than the voltage value V2, the resistance value CR3 between the control terminal 410C and the ground terminal 10G is a third resistance value (the resistance value R1). When the power supply voltage VDD is a fourth voltage value which is equal to or higher than the voltage value V2 and lower than the voltage value V3, the resistance value CR3 between the control terminal 410C and the ground terminal 10G is a fourth resistance value (the resistance value R1+R2) which is higher than the third resistance value. Accordingly, when the power supply voltage VDD is increased, the resistance value CR3 between the control terminal 410C and the ground terminal 10G can be increased. In this case, by appropriately setting the resistance values of the resistive elements, it is possible to adjust a value of a current flowing between the control terminal 410C and the ground terminal 10G when a predetermined power supply voltage VDD is applied to the semiconductor integrated circuit 400. Accordingly, characteristics different from those of other semiconductor integrated circuits can be given to the semiconductor integrated circuit 400. As a result, similarly to the aforementioned embodiments, it is possible to easily discriminate between the semiconductor integrated circuits 400. Since the resistance value CR3 between the control terminal 410C and the ground terminal 10G increases when the power supply voltage VDD increases, the value of the current flowing between the control terminal 410C and the ground terminal 10G can be made to be difficult to change, for example, when the control voltage VCT applied to the control terminal 410C increases with an increase of the power supply voltage VDD. Accordingly, by appropriately designing a change of the resistance value CR3 with a change of the power supply voltage VDD, it is possible to obtain a constant-current circuit with a simple structure. For example, in the configuration in which the resistance value between the power supply terminal 410D and another terminal increases when the power supply voltage VDD applied to the power supply terminal 410D increases, the value of the current flowing between the power supply terminal 410D and the other terminal can be made to be difficult to change when the power supply voltage VDD changes but the voltage of the other terminal is constant.

According to at least one of the aforementioned embodiments, the semiconductor integrated circuit includes a first terminal and a second terminal. When an input voltage which is externally input changes, a resistance value between the first terminal and the second terminal changes. Accordingly, it is possible to easily discriminate between the semiconductor integrated circuits.

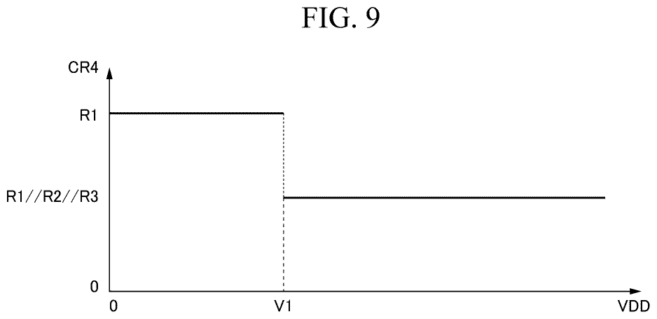

In the aforementioned embodiments, the resistance value between the first terminal and the second terminal changes in three steps with a change of the input voltage, but the present invention is not limited thereto. The resistance value between the first terminal and the second terminal may change in two steps with a change of the input voltage. FIG. 9 is a graph illustrating an example in which a resistance value CR4 between a first terminal and a second terminal changes in two steps according to a modified example. As illustrated in FIG. 9, when the power supply voltage VDD is equal to or higher than 0 V and lower than the voltage value V1, the resistance value CR4 is the resistance value R1. When the power supply voltage VDD is equal to or higher than the voltage value V1, the resistance value CR4 is a combined resistance value R1//R2//R3. When the power supply voltage VDD is higher than the voltage value V1, the resistance value CR4 does not change. The semiconductor integrated circuit 100 in which the resistance value CR4 changes as illustrated in FIG. 9 can be realized, for example, by removing the transistor 32, connecting the drain terminal of the transistor 31 to one end of the resistive element 45, and removing the path extending from the control terminal 10C to the ground terminal 10G via the resistive element 44 and the transistor 35. In this case, the resistance value CR4 is the resistance value between the control terminal 10C and the ground terminal 10G.

When the input voltage changes, the resistance value between the first terminal and the second terminal may be able to change among three or more different resistance values. The change of the resistance value between the first terminal and the second terminal may change with respect to the input voltage in any way. The resistance value between the first terminal and the second terminal may change continuously with a change of the input voltage. The input voltage may be any voltage and may be a voltage other than a power supply voltage. The input voltage may be the control voltage VCT in the aforementioned embodiments. The value of the input voltage when the resistance value between the first terminal and the second terminal changes is not particularly limited. For example, the voltage values V1 and V2 described in the aforementioned embodiments may differ depending on the embodiments. The first terminal and the second terminal may be any terminals. The first terminal and the second terminal may be terminals other than the power supply terminal, the ground terminal, and the control terminal. As along as the resistance value between the first terminal and the second terminal changes with a change of the input voltage, the circuit configuration of the semiconductor integrated circuit is not particularly limited and may employ any circuit configuration.

When the switching circuit of the semiconductor integrated circuit includes a plurality of transistors, the types of the plurality of transistors are not particularly limited. The plurality of transistors in the switching circuit may be, for example, bipolar transistors. When the switching circuit includes a plurality of resistive elements, resistance values of the plurality of resistive elements are not particularly limited.

The characteristics of the semiconductor integrated circuit in which the resistance value between the first terminal and the second terminal changes with a change of the input voltage may be used for applications other than discrimination of a semiconductor integrated circuit. For example, the resistance value between the first terminal and the second terminal may change according to the input voltage and a function of the semiconductor integrated circuit may switch according to the changing resistance value. As described above in the fourth embodiment, a circuit having a specific function which is the same as a constant-current circuit may be constructed using a change of the characteristics.

An input circuit and a semiconductor device according to an embodiment include aspects of the following remarks.

### (Remark 1)

A semiconductor integrated circuit including:
a first terminal; and
a second terminal,
wherein a resistance value between the first terminal and the second terminal changes with a change of an input voltage which is externally input.

### (Remark 2)

The semiconductor integrated circuit according to Remark 1, wherein a range of the input voltage in which the resistance value between the first terminal and the second terminal changes is lower than a voltage value of the input voltage which is input at the time of operating.

### (Remark 3)

The semiconductor integrated circuit according to Remark 1 or 2, wherein the resistance value between the first terminal and the second terminal is a first resistance value when the input voltage is a first voltage value, and
wherein the resistance value between the first terminal and the second terminal is a second resistance value lower than the first resistance value when the input voltage is a second voltage value higher than the first voltage value.

### (Remark 4)

The semiconductor integrated circuit according to any one of Remarks 1 to 3, wherein the resistance value between the first terminal and the second terminal is a third resistance value when the input voltage is a third voltage value, and
wherein the resistance value between the first terminal and the second terminal is a fourth resistance value higher than the third resistance value when the input voltage is a fourth voltage value higher than the third voltage value.

### (Remark 5)

The semiconductor integrated circuit according to any one of Remarks 1 to 4, wherein the resistance value between the first terminal and the second terminal is able to change among three or more different resistance values with a change of the input voltage.

### (Remark 6)

The semiconductor integrated circuit according to any one of Remarks 1 to 5, further including a switching circuit that is provided between the first terminal and the second terminal,
wherein the switching circuit includes a plurality of transistors and a plurality of resistive elements, and
wherein a state of the switching circuit switches with a change of the input voltage, and a combination of the resistive elements serving as a resistor between the first terminal and the second terminal changes.

### (Remark 7)

The semiconductor integrated circuit according to Remark 6, wherein the plurality of transistors include a first transistor that is provided between a terminal to which the input voltage is applied and the second terminal, and
wherein the first transistor is diode-connected.

### (Remark 8)

The semiconductor integrated circuit according to Remark 7, wherein the plurality of transistors include a plurality of the first transistors, and
wherein the plurality of the first transistors are connected in series.

### (Remark 9)

The semiconductor integrated circuit according to any one of Remarks 6 to 8, wherein the plurality of resistive elements include a resistive element that is connected between the first terminal and the second terminal without using a transistor.

### (Remark 10)

The semiconductor integrated circuit according to any one of Remarks 6 to 9, wherein the plurality of transistors include a second transistor that is provided between the first terminal and the second terminal, and
wherein the plurality of resistive elements include a resistance element that is connected in series to the second transistor between the first terminal and the second terminal.

### (Remark 11)

The semiconductor integrated circuit according to any one of Remarks 1 to 6, further including a third terminal,
wherein the third terminal is a terminal to which the input voltage is applied.

### (Remark 12)

The semiconductor integrated circuit according to any one of Remarks 1 to 6, wherein the first terminal is a terminal to which the input voltage is applied.

What is claimed is:

1. A semiconductor integrated circuit comprising:
a first terminal; and
a second terminal,
wherein a resistance value between the first terminal and the second terminal changes with a change of an input voltage which is externally input.

2. The semiconductor integrated circuit according to claim 1, wherein a range of the input voltage in which the resistance value between the first terminal and the second terminal changes is lower than a voltage value of the input voltage which is input at the time of operating.

3. The semiconductor integrated circuit according to claim 1, wherein the resistance value between the first terminal and the second terminal is a first resistance value when the input voltage is a first voltage value, and
wherein the resistance value between the first terminal and the second terminal is a second resistance value lower than the first resistance value when the input voltage is a second voltage value higher than the first voltage value.

4. The semiconductor integrated circuit according to claim 1, wherein the resistance value between the first terminal and the second terminal is a third resistance value when the input voltage is a third voltage value, and
wherein the resistance value between the first terminal and the second terminal is a fourth resistance value higher than the third resistance value when the input voltage is a fourth voltage value higher than the third voltage value.

5. The semiconductor integrated circuit according to claim 1, wherein the resistance value between the first terminal and the second terminal is able to change among three or more different resistance values with a change of the input voltage.

6. The semiconductor integrated circuit according to claim 1, further comprising a switching circuit that is provided between the first terminal and the second terminal,
wherein the switching circuit includes a plurality of transistors and a plurality of resistive elements, and
wherein a state of the switching circuit switches with a change of the input voltage, and a combination of the resistive elements serving as a resistor between the first terminal and the second terminal changes.

7. The semiconductor integrated circuit according to claim 6,
wherein the plurality of transistors include a first transistor that is provided between a terminal to which the input voltage is applied and the second terminal, and
wherein the first transistor is diode-connected.

8. The semiconductor integrated circuit according to claim 7,
wherein the plurality of transistors include a plurality of the first transistors, and
wherein the plurality of the first transistors are connected in series.

9. The semiconductor integrated circuit according to claim 6,
wherein the plurality of resistive elements include a resistive element that is connected between the first terminal and the second terminal without using a transistor.

10. The semiconductor integrated circuit according to claim 6,
wherein the plurality of transistors include a second transistor that is provided between the first terminal and the second terminal, and
wherein the plurality of resistive elements include a resistance element that is connected in series to the second transistor between the first terminal and the second terminal.

11. The semiconductor integrated circuit according to claim 1, further comprising a third terminal,
wherein the third terminal is a terminal to which the input voltage is applied.

12. The semiconductor integrated circuit according to claim 1, wherein the first terminal is a terminal to which the input voltage is applied.
